(19) United States
(12) Patent Application Publication
(10) Pub. No.: US 2011/0308615 A1
(43) Pub. Date: Dec. 22, 2011

(54) CRYSTAL SILICON PROCESSES AND PRODUCTS

(75) Inventors: Charles W. Teplin, Golden, CO (US); Howard M Branz, Golden, CO (US); Lee Heatherly, Oak Ridge, TN (US); Mariappan Parans Paranthaman, Oak Ridge, TN (US)

(73) Assignee: ALLIANCE FOR SUSTAINABLE ENERGY, LLC, Golden, CO (US)

(21) Appl. No.: 13/148,925

(22) PCT Filed: Feb. 12, 2009
(86) PCT No.: PCT/US09/33937

§ 371 Date: Aug. 10, 2011

(51) Int. Cl. H01L 31/0256; C30B 25/02; H01L 31/18; H01L 21/20; H01L 31/036; B32B 9/04; C30B 25/18

(52) U.S. Cl. 136/261; 428/446; 117/95

(57) ABSTRACT

Crystal silicon processes and products (100) are disclosed. In any exemplary embodiment, a biaxially textured metal substrate (110) was fabricated by the Rolling-Assisted Biaxially Textured Substrate (RABiTS) process. Electron beam evaporation was used to grow buffer layers (120) heteroepitaxially on the metal substrate (110) as a buffer layer (120). After growth of the buffer layer (120), a silicon layer was grown using hot wire chemical vapor deposition (HWCVD). The silicon film had the same grain size as the underlying metal substrate (110). In addition, the orientation of these grains matched the orientations of the underlying metal substrate (110).

### CONTRACTUAL ORIGIN

The United States Government has rights in this invention under Contract No. DE-AC36-08G028308 between the United States Department of Energy and the Alliance for Sustainable Energy, LLC, the Manager and Operator of the National Renewable Energy Laboratory.

### Technical Field

The described subject matter relates to crystal silicon processes and products.

### BACKGROUND

Crystal silicon offers advantages for use in a wide variety of applications and fields of use. For example, crystal silicon may be used as the primary absorbing semiconductor in photovoltaics devices. However, the cost of manufacturing silicon wafers is very expensive, amounting to about half the cost of a solar module. The largest crystal silicon size available is limited to 12 inches in diameter for now. Further, there is no efficient way to use the crystal silicon. That is, less than 10 microns of silicon is needed to fabricate an efficient solar cell. But due to sawing losses and difficulties in handling very thin wafers, applications typically use on the order of 150-400 microns of silicon.

An alternate approach is to grow silicon directly onto an inexpensive substrate. In order to accomplish this without compromising the electronic properties of the silicon, one must grow the silicon in such a way that the crystalline grains are very large (i.e., larger than the silicon layer thickness in the final device structure) and, preferably well-oriented with respect to each other (i.e., biaxially textured).

One method for implementing this approach is to start with a substrate material having an oriented seed layer. The silicon layer can then be deposited onto the oriented seed layer, thereby maintaining both the seed grain size and texture. Of course in order to be considered a worthwhile alternative to using a silicon wafer, the substrate material and oriented seed layer should be inexpensive when compared to the silicon wafer.

The foregoing examples of the related art and limitations related therewith are intended to be illustrative and not exclusive. Other limitations of the related art will become apparent to those of skill in the art upon a reading of the specification and a study of the drawings.

### SUMMARY

The following embodiments and aspects thereof are described and illustrated in conjunction with systems, tools and methods that are meant to be exemplary and illustrative, not limiting in scope. In various embodiments, one or more of the above-described problems have been reduced or eliminated, while other embodiments are directed to other improvements.

Exemplary processes start with a biaxially textured metal foil substrate having large grains that are biaxially textured with the (100) crystal orientation normal to the surface. Physical vapor deposition process, such as electron beam evaporation, is then used to grow one or more buffer layer heteroepitaxially on the foil substrate. It is also possible to use other thin film deposition techniques such as sputtering, chemical vapor deposition, chemical solution deposition, etc. The silicon layer is then grown on the buffer layer(s) using hot-wire chemical vapor deposition (HWCVD).

Exemplary products include a silicon film having the same grain size as the underlying metal foil substrate, and the orientation of these grains matches the orientations of the underlying metal foil substrate.

In addition to the exemplary aspects and embodiments described above, further aspects and embodiments will become apparent by reference to the drawings and by study of the following descriptions.

### BRIEF DESCRIPTION OF THE DRAWINGS

Exemplary embodiments are illustrated in referenced figures of the drawings. It is intended that the embodiments and figures disclosed herein are to be considered illustrative rather than limiting.

FIG. 1 is a high-level block diagram of an exemplary crystal silicon device.

FIGS. 2a-c are transmission electron microscopy (TEM) images showing a cross-section of a heteroepitaxial structure formed according to exemplary embodiments described herein.

FIG. 3 is a scanning electron microscopy (SEM) image showing a top surface of a heteroepitaxial structure formed according to exemplary embodiments described herein.

FIG. 4 is an x-ray diffraction (XRD) plot of a heteroepitaxial structure formed according to exemplary embodiments described herein.

FIG. 5 is a pole figure of a heteroepitaxial structure formed according to exemplary embodiments described herein.

FIG. 6a is an electron beam scattered diffraction (EBSD) image of a heteroepitaxial structure formed according to exemplary embodiments described herein.

FIG. 6b is a pole figure of a heteroepitaxial structure formed according to exemplary embodiments described herein.

### DETAILED DESCRIPTION

Briefly, embodiments disclosed herein describe crystal silicon processes and products which may have a wide variety of commercial and other applications. An exemplary crystal silicon device may include a biaxially textured metal substrate, at least one buffer layer grown heteroepitaxially on the metal substrate, and a silicon layer having a grain size substantially the same as the metal substrate. The crystal silicon device may be produced by growing at least one buffer layer heteroepitaxially on a metal substrate, and growing a silicon layer on the at least one buffer layer. The crystal silicon photovoltaic device may be characterized as the silicon layer having substantially the same grain size as the metal substrate, and the grains substantially matching orientations of the metal substrate. Exemplary embodiments may be better understood with reference to the figures and following discussion.

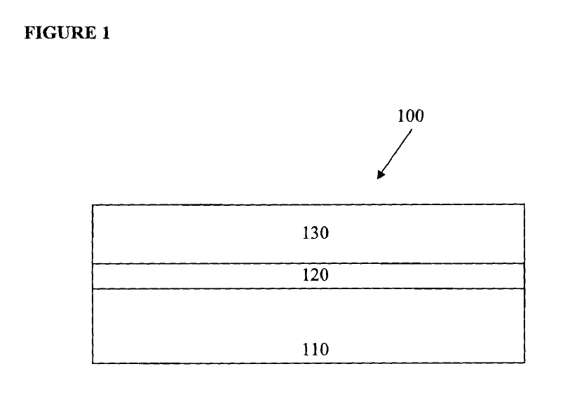

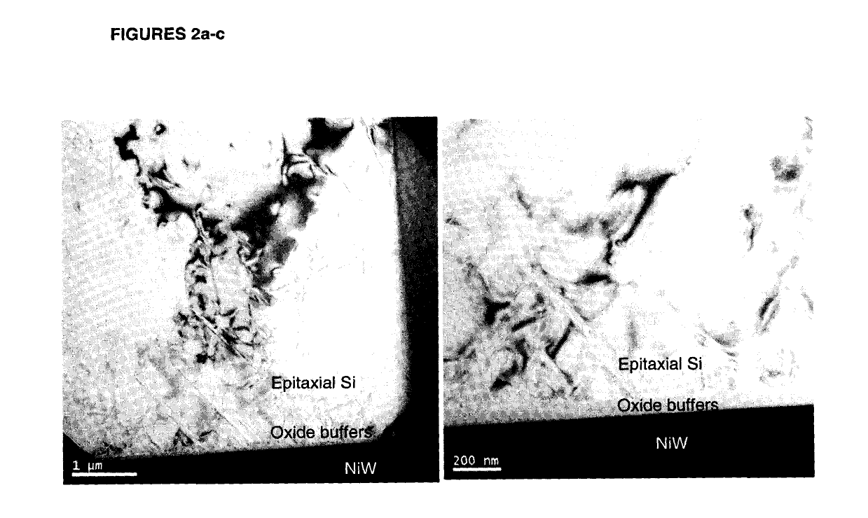

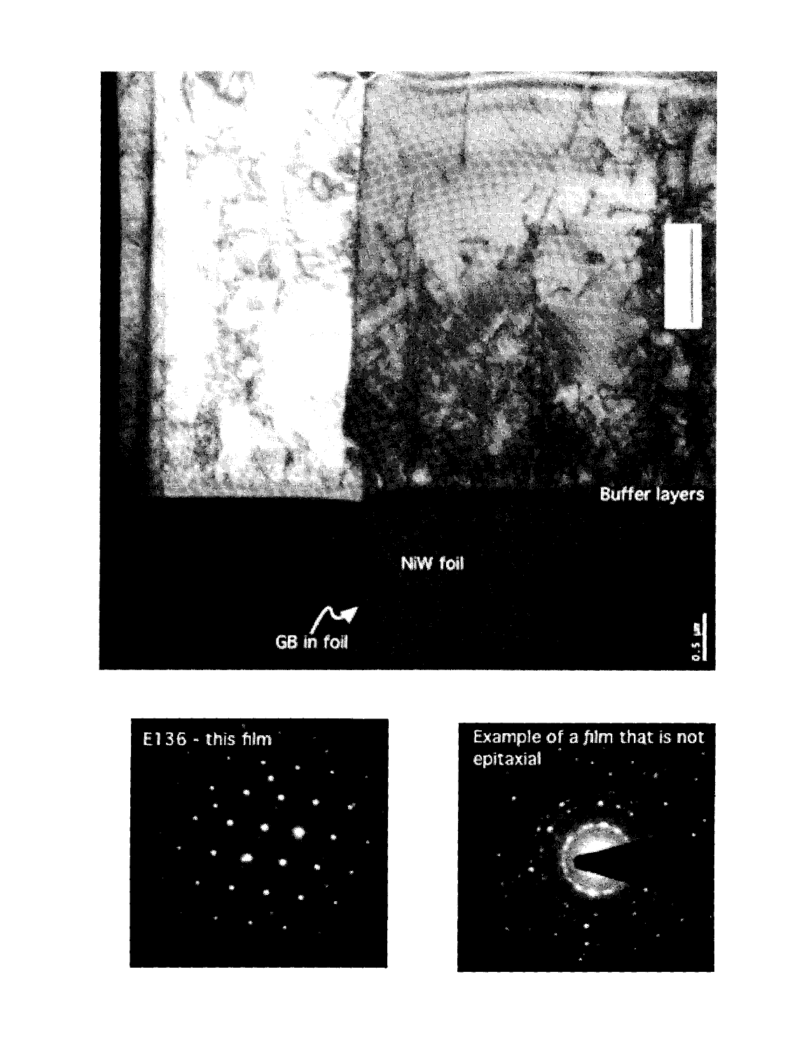

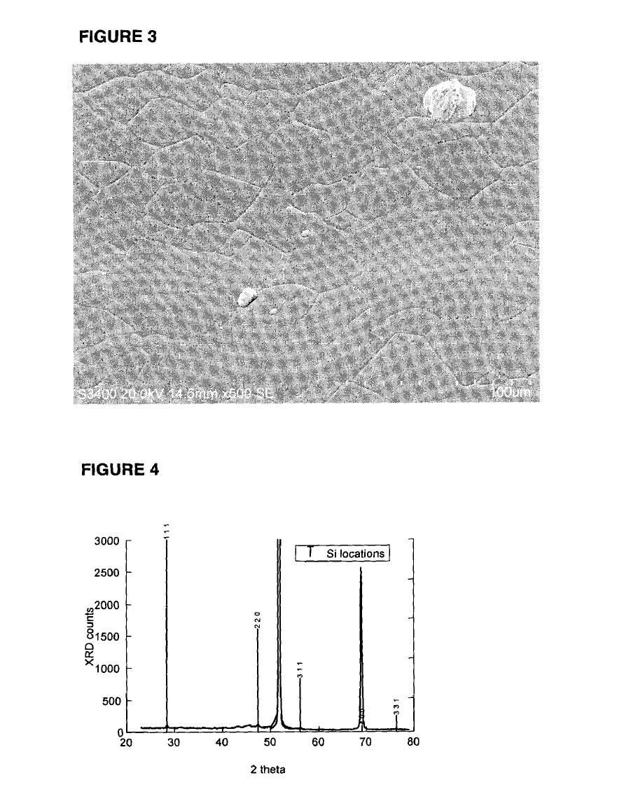

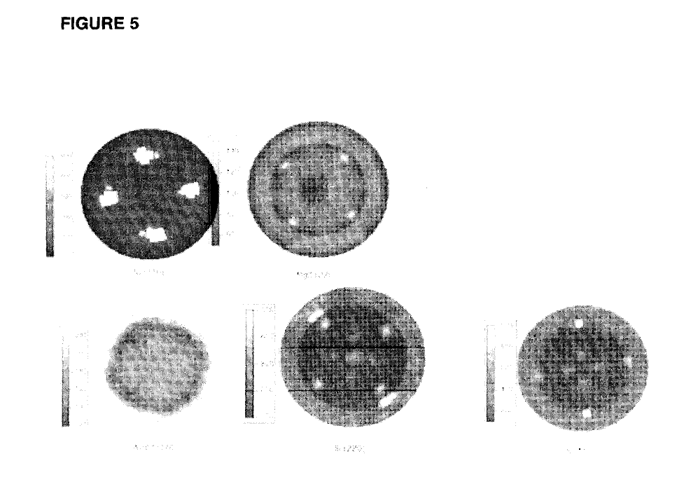

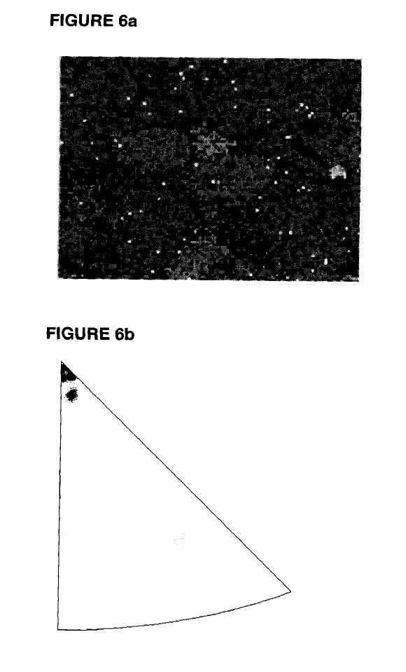

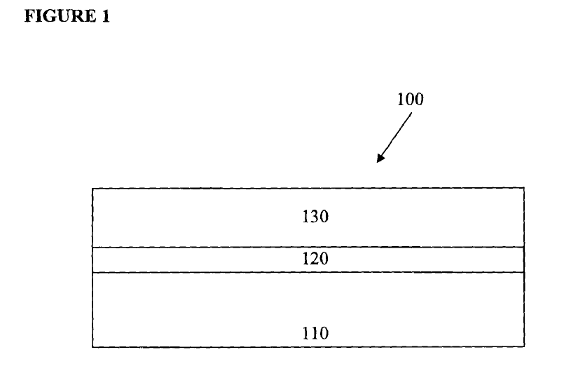

FIG. 1 is a high-level block diagram of an exemplary crystal silicon device 100. In one embodiment, the crystal silicon device is a photovoltaic device; in another embodiment, the crystal silicon device is a thin-film transistor; in another embodiment the crystal silicon device is a light detector; however, the embodiments described herein are not limited to any particular application. The crystal silicon device 100 may include a biaxially textured metal substrate 110. The crystal silicon device 100 may also include at least one buffer layer (e.g., a buffer layer 120) grown heteroepitaxially on the metal substrate 110. The crystal silicon device 100 may also include a silicon layer 130.

In an exemplary embodiment, the metal substrate 110 is a biaxially textured NiW foil fabricated by the Rolling-Assisted Biaxially Textured Substrate (RABiTS) process. The RABiTS process is well known in the art, for example, as described by Amit Goyal, et al. in “The RABiTS Approach: Using Rolling-Assisted Biaxially Textured Substrates for High-Performance YBCO Superconductors,” MRS BULLETIN, p. 553 (August 2004).

RABiTS substrates are commercially employed in manufacturing biaxially textured superconducting wires, so the cost is relatively low. The RABiTS process results in large grains with sizes around 35-50 microns that are biaxially textured with the (100) crystal orientation normal to the surface. The RABiTS substrate thickness is generally in the range of about 25-100 microns (e.g., 50 microns).

Next, electron beam evaporation is used to grow the buffer layer 120. Electron beam evaporation is a type of physical vapor deposition in which a target material is bombarded with an electron beam. The electron beam causes atoms from the target to evaporate. The evaporated atoms then precipitate in solid form, coating the substrate in the deposition chamber with a thin layer of the target material, hence forming the buffer layer.

In an exemplary embodiment, the buffer layer 120 may include about 60 nm of MgO and 120 nm of γ-Al₂O₃ grown heteroepitaxially on the foil. These oxide layers serve two functions. First, the oxide layers reduce or altogether prevent diffusion of Ni or W from the metal foil into the silicon layer. Second, the oxide layers provide chemical compatibility that enables subsequent silicon heteroepitaxy.

The MgO may be deposited by evaporating crystalline MgO using an e-beam voltage in the range of about 5-14 keV (e.g., 8-9 keV) and a deposition rate in the range of about 1-100 Ang/sec (e.g., 2 Ang/s). The H₂O partial pressure may be in the range of about 10⁻⁴ to 10⁻⁶ Torr (e.g., 5 or 6×10⁻⁵ Torr), and the deposition temperature may be in the range of about 300 to 800° C. (e.g., 325° C.). Using a thickness in the range of about 10-300 nm (e.g., 60 nm) takes about 5 minutes to deposit at about 2 ang/s.

The Al₂O₃ may be deposited by evaporating crystalline Al₂O₃ also at an e-beam voltage in the range of about 5-14 keV (e.g., 8-9 keV) and a deposition rate in the range of about 1-100 Ang/sec (e.g., 2 Ang/s). The partial pressure of H₂O may be in the range of about 10⁻⁴ to 10⁻⁶ Torr (e.g., 5 or 6×10⁻⁵ Torr). The temperature during the deposition may be in the range of about 300 to 800° C. (e.g., 600° C.). Using a thickness in the range of about 10-300 nm (e.g., 120 nm) takes about 10 minutes to deposit at about 2 Ang/s. Deposition may also be possible in a wide range of other temperatures by adjusting other growth parameters.

The buffer layer is not limited to any particular composition. Other exemplary buffer layers may include, but are not limited to Ir, TiN, MgO, Al₂O₃, Cu, Ag, Pd, Pt, Mo, La₂Zr₂O₇, Gd₂Zr₂O₇, LaAlO₃, LaSrMnO₃.

After growth of the γ-Al₂O₃, or other buffer layer(s), the silicon layer 130 may be grown using hot-wire chemical vapor deposition (HWCVD). HWCVD is a chemical process commonly used to produce high-purity, high-performance thin films. The use of HWCVD is a technique that is easily scaled to large areas at reasonable costs. During the HWCVD process, an electrical current is passed through a wire composed of W, Ta, Ir, Rh, C or other pure material or alloy material to raise its temperature to between about 1500 and 2300° C. and this hot wire is exposed to one or more precursor gas materials to produce reactive gaseous products which reacts with the substrate surface to form the thin film. This film can be silicon or silicon doped with P, B, As, Ge or another semiconductor dopant atom. In this embodiment, the HWCVD process forms a silicon thin film on the oxide layers on the RABiTS substrate.

At substrate temperatures above about 600° C. but up to about 800° C., the resulting heteroepitaxial silicon film has substantially the same grain size as the underlying NiW foil. In addition, the orientation of these grains substantially matches the orientations of the underlying NiW foil.

In summary, an exemplary process may be as follows:

1. use the RABiTS process to fabricate a NiW foil with large (about 50 μm), oriented grains;

2. deposit a heteroepitaxial MgO layer using e-beam evaporation at about 550° C.;

3. deposit a heteroepitaxial γ-Al₂O₃ layer using e-beam evaporation at about 550° C.; and

4. deposit a heteroepitaxial silicon layer using HWCVD at about 600-800° C.

It is noted that the above description is intended only as an example of crystal silicon products and processes. Still other embodiments will be readily appreciated by those having ordinary skill in the art after becoming familiar with the teachings herein. It is readily appreciated that applications of this technology may include, but are not limited to, use in the photovoltaics field.

### EXAMPLE

In this example, a biaxially textured NiW foil was used. The NiW foil was fabricated by the Rolling-Assisted Biaxially Textured Substrate (RABiTS) process. The process was demonstrated on two types of RABiTS NiW, both vacuum cast Ni-5W, and non-vacuum cast Ni-3W. The NiW foil had large (−50 μm), oriented grains.

Electron beam evaporation was used at about 550° C. to grow 60 nm of MgO and 120 nm of γ-Al₂O₃ heteroepitaxially on the NiW foil. After growth of the γ-Al₂O₃, the silicon layer was grown using HWCVD. The specific deposition conditions used for the silicon growth were:

about 20 sccm of SiH₄ flow;

a single, coiled tungsten filament about 12 inches long, heated with about a 16 A current;

about 10 mTorr pressure in the chamber during growth;

substrate temperatures between about 600° C. to 800° C.; and

a base pressure of about 5×10⁻⁷ Torr.

At temperatures above 600° C., a heteroepitaxial silicon film was grown. The silicon film had the same grain size as the underlying NiW foil. In addition, the orientation of these grains matched the orientations of the underlying NiW foil, resulting in biaxial texture of the silicon layer, as can be seen in the figures.

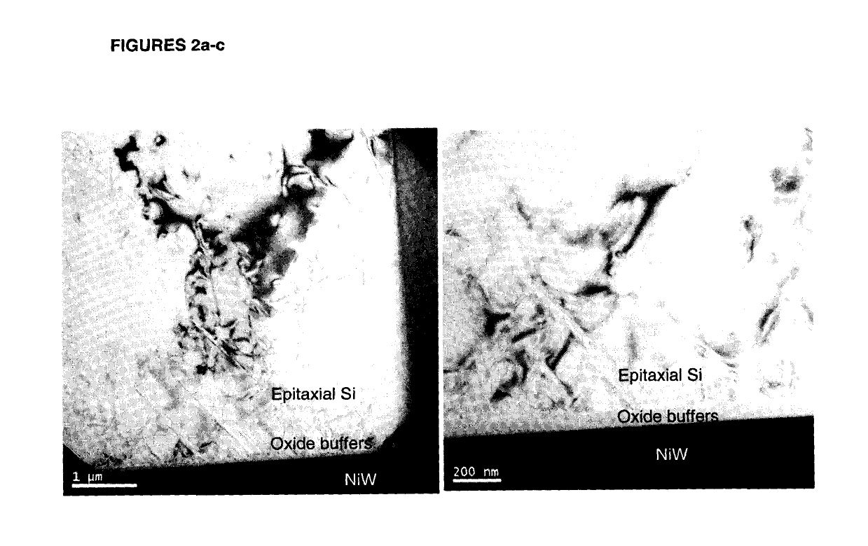

FIGS. 2a-c are transmission electron microscopy (TEM) images showing a cross-section of a heteroepitaxial structure formed according to the Example described above. A NiW substrate is shown in the bottom portion of the images; a buffer layer is shown in the middle portion of the images; and a heteroepitaxial silicon layer is shown in the top portion of the images. Very few crystal defects are present in the TEM images, indicating good alignment and good quality heteroepitaxy.

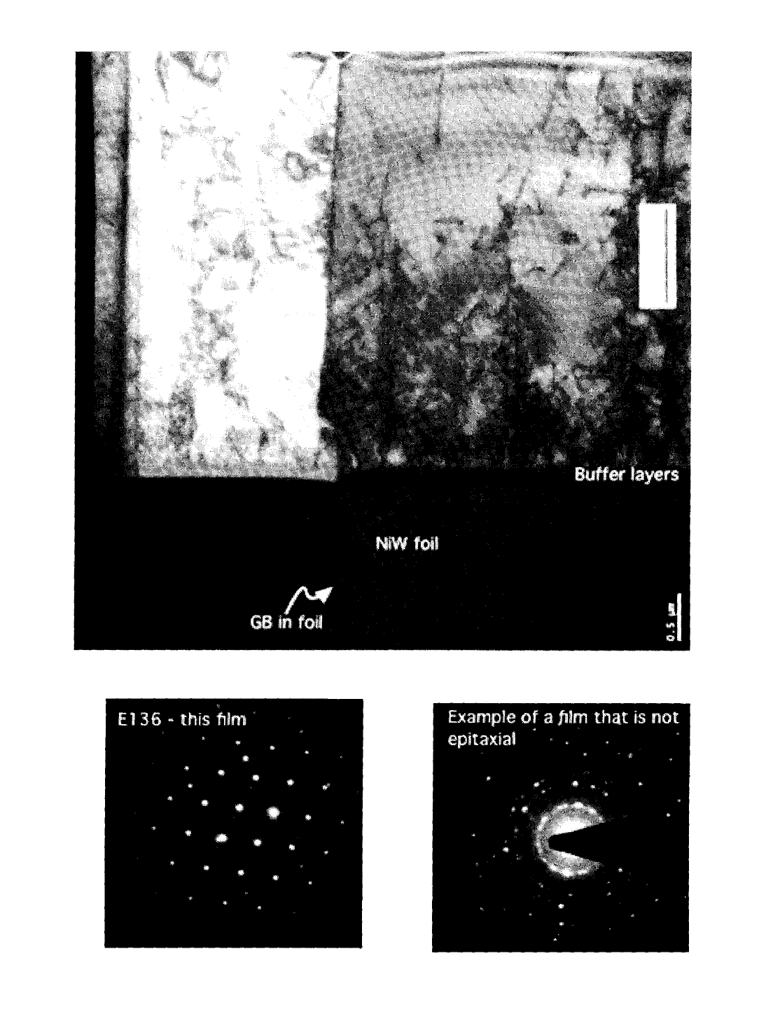

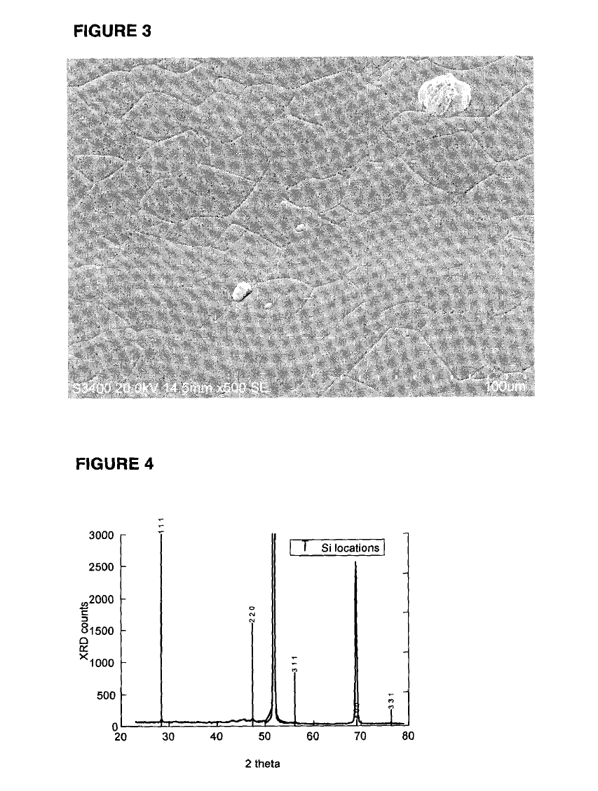

FIG. 3 is a scanning electron microscopy (SEM) image showing a top surface of a heteroepitaxial structure formed according to the Example described above. A carrier diffusion length of about 5 microns was measured on the heteroepitaxial films using the decay of the luminescence at increasing distances from an electron-beam excitation at a point.

FIG. 4 is a typical x-ray diffraction (XRD) plot of a heteroepitaxial structure formed according to the Example described above. The peak that is observed in the plot at about 52° results from the (200) peak of NiW foil substrate. The peak that is observed in the plot at about 69° results from the silicon (400) peak. This peak, and the lack of other peaks, is consistent with what would be expected for silicon heteroepitaxy with the (100) crystal direction normal to the surface. Other silicon peaks are visible because the XRD data is taken using a large area detector that includes areas away from 0°.

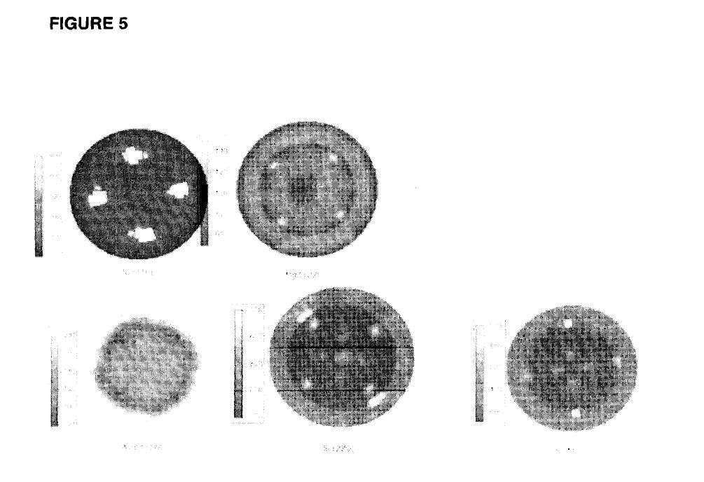

FIG. 5 is a set of XRD pole figures of a heteroepitaxial structure formed according to exemplary embodiments described herein. The dominant (220) peaks of all 4 layers (NiW substrate, MgO, Al₂O₃, Si) are all either at the same phi angles or 90° offset. This is consistent with heteroepitaxial alignment of all layers.

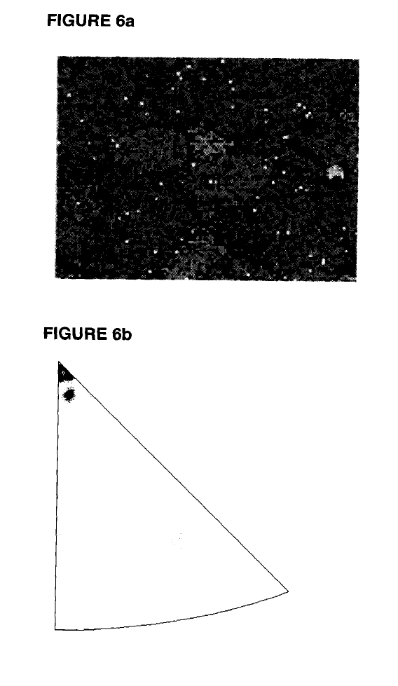

FIG. 6a is an electron beam scattered diffraction (EBSD) image of a heteroepitaxial structure formed according to exemplary embodiments described herein. The red pixels indicate scattering consistent with (100) oriented silicon. Other colors indicate different orientations or a rough surface preventing accurate measurement. FIG. 6b is the EBSD pole figure of a heteroepitaxial structure formed according to exemplary embodiments described herein. The pole figure shows that the grains are (100) oriented (i.e., the grains are well aligned). It is noted that the example discussed above is provided for purposes of illustration and is not intended to be limiting. Still other embodiments and modifications are also contemplated.

While a number of exemplary aspects and embodiments have been discussed above, those of skill in the art will recognize certain modifications, permutations, additions and sub combinations thereof. It is therefore intended that the following appended claims and claims hereafter introduced are interpreted to include all such modifications, permutations, additions and sub-combinations as are within their true spirit and scope.

1. A crystal silicon product comprising:
a biaxially textured metal substrate;
a buffer layer including at least one buffer layer grown heteroepitaxially on the metal substrate; and
a silicon layer having a grain size substantially the same as the metal substrate.

2. The crystal silicon product of claim 1, wherein grains in the silicon layer substantially match orientations of the metal substrate.

3. A crystal silicon product produced by:
growing at least one buffer layer heteroepitaxially on a metal substrate;
growing a silicon layer on the at least one buffer layer; and
wherein the silicon layer has substantially the same grain size as the metal substrate, and the grains substantially match orientations of the metal substrate.

4. The crystal silicon product produced by the process of claim 3 wherein the metal substrate is fabricated by Rolling-Assisted Biaxially Textured Substrate (RABiTS).

5. The crystal silicon product produced by the process of claim 3 wherein electron beam evaporation is used to grow the buffer layers.

6. The crystal silicon product produced by the process of claim 3 wherein the silicon layer is grown using hot wire chemical vapor deposition (HWCVD).

7. A crystal silicon photovoltaic device comprising:
a biaxially textured metal substrate;
at least one buffer layer grown heteroepitaxially on the metal substrate; and
a silicon layer having a grain size substantially the same as the metal substrate.

8. The crystal silicon photovoltaic device of claim 7 produced by:
growing at least one buffer layer heteroepitaxially on a metal substrate; and
growing a silicon layer on the at least one buffer layer.

9. The crystal silicon photovoltaic device of claim 7 wherein the silicon layer has substantially the same grain size as the metal substrate, and the grains substantially match orientations of the metal substrate.

10. The crystal silicon photovoltaic device of claim 9 wherein the silicon layer is characterized by x-ray diffraction as being heteroepitaxial.

11. The crystal silicon photovoltaic device of claim 9 wherein the silicon layer is characterized by pole diagram as being heteroepitaxial.

12. The crystal silicon photovoltaic device of claim 9 wherein the silicon layer is characterized by SEM images as being heteroepitaxial.

13. The crystal silicon photovoltaic device of claim 9 wherein the silicon layer is characterized by TEM images as being heteroepitaxial.

14. The crystal silicon photovoltaic device of claim 7 wherein the metal substrate is fabricated by Rolling-Assisted Biaxially Textured Substrate (RABiTS).

15. The crystal silicon photovoltaic device of claim 7 wherein electron beam evaporation is used to grow the buffer layers.

16. The crystal silicon photovoltaic device of claim 15 wherein electron beam evaporation is at about 550° C.

17. The crystal silicon photovoltaic device of claim 7 wherein the silicon layer is grown using hot wire chemical vapor deposition (HWCVD).

18. The crystal silicon photovoltaic device of claim 17 wherein HWCVD is at the following conditions:
about 20 sccm of SiH₄ flow;
a single, coiled tungsten filament about 12 inches long, heated with about a 16 A current;
about 10 mTorr pressure in the chamber during growth;
substrate temperatures between about 600° C. to 800° C.; and
a base pressure of about 5×10⁻⁷ Torr.

19. The crystal silicon photovoltaic device of claim 7 wherein the metal substrate is vacuum cast Ni-5W.

20. The crystal silicon photovoltaic device of claim 7 wherein the metal substrate is non-vacuum cast Ni-3W.

21. The crystal silicon photovoltaic device of claim 7 wherein the metal substrate is NiW foil with large (about 50 μm), oriented grains.

22. The crystal silicon photovoltaic device of claim 7 wherein at least one buffer layer includes about 60 nm of MgO and 120 nm of γ-Al₂O₃.
